(19) United States
(12) Patent Application Publication
(10) Pub. No.: US 2020/0098847 A1
(43) Pub. Date: Mar. 26, 2020

(54) DISPLAY SUBSTRATE, METHOD FOR MANUFACTURING SAME, AND DISPLAY DEVICE

(71) Applicant: BOE TECHNOLOGY GROUP CO., LTD., Beijing (CN)

(72) Inventors: Shuai Zhang, Beijing (CN); Libin Liu, Beijing (CN); Yueping Zuo, Beijing (CN); Qiuhua Meng, Beining (CN)

(73) Assignee: BOE TECHNOLOGY GROUP CO., LTD., Beijing (CN)

(21) Appl. No.: 16/419,234

(22) Filed: May 22, 2019

(30) Foreign Application Priority Data
Sep. 20, 2018 (CN) 201811116878.6

(51) Int. Cl. H01L 27/32; H01L 51/52

(52) U.S. Cl. CPC H01L 27/3279; H01L 2227/323; H01L 51/5237; H01L 27/323

(57) ABSTRACT

The present disclosure provides a display substrate, a method for manufacturing the same, and a display device. The display substrate comprises a display region, and a peripheral circuit located on a periphery of the display region and provided with a signal line. The display substrate further comprises at least one conductive pattern located on a thin film encapsulation layer of the display substrate and connected in substantially parallel to the signal line.

### CROSS-REFERENCE TO RELATED APPLICATION

This application claims a priority to Chinese Patent Application No. 201811116878.6 filed on Sep. 20, 2018, the disclosures of which are incorporated in their entirety by reference herein.

### TECHNICAL FIELD

The present disclosure relates to the field of display technology, in particular to a display substrate, a method for manufacturing the same, and a display device.

### BACKGROUND

An organic light-emitting diode (OLED) is a novel current-type semiconductor light-emitting device in which organic material is excited to emit light by means of the control of carrier injection and recombination of the device. Specifically, organic light-emitting diodes can be divided into two driving types: active matrix driving OLEDs (AMOLEDs) and passive matrix driving OLEDs (PMOLEDs). As compared with passive matrix driving, active matrix driving provides a thin film transistor (TFT) and a charge storage capacitor for each sub-pixel, and thus enables an improved driving capability, makes it easy to achieve high resolution and high luminance, and provides advantages of high operation efficiency, low power consumption and the like. An AMOLED is easy to integrate into a display screen, makes it easier to increase circuit integration and realize large-area display, and is therefore an ideal device for low-power large-size display terminals.

### SUMMARY

In a first aspect, some embodiments of the present disclosure provide a display substrate including: a display region; a peripheral circuit located on a periphery of the display region and provided with a signal line; and at least one conductive pattern located on a thin film encapsulation layer of the display substrate and connected in substantially parallel to the signal line.

According to some embodiments of the present disclosure, the conductive pattern is located in the display region.

According to some embodiments of the present disclosure, the display substrate includes a plurality of light-emitting units located in the display region, and an orthogonal projection of the conductive pattern on a base substrate of the display substrate does not coincide at all or in part with orthogonal projections of the light-emitting units on the base substrate.

According to some embodiments of the present disclosure, the display substrate further includes a touch electrode bridge and a touch electrode, which are located on the thin film encapsulation layer but disposed in different layers, and the conductive pattern is formed of a same material and in a same layer as the touch electrode bridge.

According to some embodiments of the present disclosure, an orthogonal projection of the conductive pattern on a base substrate of the display substrate does not coincide at all or in part with an orthogonal projection of the touch electrode on the base substrate.

According to some embodiments of the present disclosure, the signal line is a Vss signal line.

According to some embodiments of the present disclosure, the display substrate is an OLED display substrate or an AMOLED display substrate.

According to some embodiments of the present disclosure, when the display substrate is the AMOLED display substrate, its bezel has a width of 0.5 mm or less.

In a second aspect, some embodiments of the present disclosure provide a display device that includes a display substrate. The display substrate includes: a display region; a peripheral circuit located on a periphery of the display region and provided with a signal line; and at least one conductive pattern located on a thin film encapsulation layer of the display substrate and connected in substantially parallel to the signal line.

According to some embodiments of the present disclosure, the conductive pattern is located in the display region.

According to some embodiments of the present disclosure, the display substrate includes a plurality of light-emitting units located in the display region, and an orthogonal projection of the conductive pattern on a base substrate of the display substrate does not coincide at all or in part with orthogonal projections of the light-emitting units on the base substrate.

According to some embodiments of the present disclosure, the display substrate further includes a touch electrode bridge and a touch electrode, which are located on the thin film encapsulation layer but disposed in different layers, and the conductive pattern is formed of a same material and in a same layer as the touch electrode bridge.

According to some embodiments of the present disclosure, an orthogonal projection of the conductive pattern on a base substrate of the display substrate does not coincide at all or in part with an orthogonal projection of the touch electrode on the base substrate.

According to some embodiments of the present disclosure, the signal line is a Vss signal line.

According to some embodiments of the present disclosure, the display substrate is an OLED display substrate or an AMOLED display substrate.

According to some embodiments of the present disclosure, when the display substrate is the AMOLED display substrate, its bezel has a width of 0.5 mm or less.

In a third aspect, some embodiments of the present disclosure provide a method for manufacturing a display substrate that includes a display region, and a peripheral circuit which is located on a periphery of the display region and provided with a signal line. The method includes forming at least one conductive pattern connected in substantially parallel to the signal line on a thin film encapsulation layer of the display substrate.

According to some embodiments of the present disclosure, the display substrate includes a plurality of light-emitting units located in the display region, and the forming the at least one conductive pattern includes forming the at least one conductive pattern in the display region, wherein an orthogonal projection of the conductive pattern on a base substrate of the display substrate does not coincide at all or in part with orthogonal projections of the light-emitting units on the base substrate.

According to some embodiments of the present disclosure, the display substrate further includes a touch electrode bridge and a touch electrode, which are located on the thin film encapsulation layer but disposed in different layers, and the forming the at least one conductive pattern includes forming the conductive pattern and the touch electrode bridge simultaneously by a single patterning process.

According to some embodiments of the present disclosure, the forming the forming the at least one conductive pattern connected in substantially parallel to the signal line on the thin film encapsulation layer of the display substrate is performed by a bonding process.

According to some embodiments of the present disclosure, the method further includes forming a touch electrode bridge and a touch electrode on the thin film encapsulation layer of the display substrate by a flexible multiple layer on cell (FMLOC) process.

According to some embodiments of the present disclosure, the manufactured display substrate is an OLED display substrate or an AMOLED display substrate.

### BRIEF DESCRIPTION OF THE DRAWINGS

In order to illustrate the technical solutions of the embodiments of the present disclosure more clearly, accompanying drawings necessary for the description of the embodiments of the present disclosure will be briefly described. Apparently, the drawings described in the following are merely some of the embodiments of the present disclosure, and based on these drawings, other drawings can be further obtained by a person having ordinary skills in the art without exercising inventive skills.

FIG. 1 is a schematic cross-sectional view of a display substrate provided by an embodiment of the present disclosure; and

FIG. 2 is a schematic plan view of the display substrate provided by the embodiment of the present disclosure.

### DETAILED DESCRIPTION

To make the technical problem to be solved, technical solutions and advantages of the present disclosure more apparent, detailed description will be given hereinafter in conjunction with the drawings and particular embodiments.

As well known in the art, AMOLED display products still have some shortcomings in some respects. For example, due to technical characteristics, a BP (Backplane, an active backplane) peripheral circuit layout structure of an AMOLED display product needs to occupy a considerable area, and a border width of the AMOLED display product is thus significantly larger than a border width of a LTPS-LCD (Low Temperature Poly-silicon-Liquid Crystal Display) product. In addition, due to the influence of temperature rise caused by Joule heat of a current concentrating region in the peripheral circuit on the lifetime of a nearby OLED device, the peripheral circuit needs to occupy a larger area to reduce wiring resistance, thus reducing the temperature rise caused by Joule heat of the circuit. In summary, due to the various technical conditions, the BP peripheral circuit of the AMOLED display product needs to occupy a larger area, which affects the development of the AMOLED display product towards a narrow border.

In this regard, embodiments of the present disclosure provide a display substrate, a method for manufacturing the same, and a display device, which are advantageous for achieving a narrow border of an AMOLED display product for example.

An embodiment of the present disclosure provides a display substrate that includes a display region, and a peripheral circuit which is located on a periphery of the display region and which is provided with a signal line. The display substrate further includes at least one conductive pattern located on a thin film encapsulation layer of the display substrate and connected in substantially parallel to the signal line.

In this embodiment, the conductive pattern is provided on the thin film encapsulation layer of the display substrate, and connected in substantially parallel to the signal line of the peripheral circuit of the display substrate. In this way, the resistance of the signal line of the peripheral circuit can be reduced, and it is not necessary to set the width of the peripheral circuit to be large so that enough space is reserved to increase the width of the signal line, thereby reducing the requirement for the wiring width of the peripheral circuit. As a result, it is possible to improve a situation in which there is excessive IR-drop and local heat since an excessively narrow Vss signal line has increased resistance when the AMOLED display product has a narrow bezel, and this is conducive to achieving the narrow border of the AMOLED display product.

Since an area of the display region is much larger than that of a region where the peripheral circuit is located, the display region has larger layout space, and the conductive pattern may be optionally arranged in the display region. In this way, it is possible to accommodate more conductive patterns, or to accommodate a conductive pattern to have a larger width. Therefore, it is possible to effectively reduce the resistance of the signal line of the peripheral circuit.

Specifically, the display substrate is an OLED display substrate, and includes a plurality of light-emitting units located in the display region. In order not to affect the display of the display substrate, an orthogonal projection of the conductive pattern on a base substrate of the display substrate does not coincide at all or in part with orthogonal projections of the light-emitting units on the base substrate. Of course, when the conductive pattern is made of a transparent conductive material, the orthogonal projection of the conductive pattern on the base substrate of the display substrate coincides completely or partially with the orthogonal projections of the light-emitting units on the base substrate of the display substrate. However, the electrical conductivity of a metal material is generally better than that of a transparent conductive material. Therefore, the conductive pattern is alternatively made of a metal material such as Al, Cu, or Ag. Since the metal material is opaque, it is necessary to design the conductive pattern in such a manner that the orthogonal projection of the conductive pattern on the base substrate of the display substrate does not coincide at all or in part with the orthogonal projections of the light-emitting units on the base substrate.

Further, when the display substrate further incorporates a touch function, the display substrate further includes a touch electrode bridge and a touch electrode, which are located on the thin film encapsulation layer but disposed in different layers, and the conductive pattern is optionally formed of a same material and in a same layer as the touch electrode bridge. In this way, the touch electrode bridge and the conductive pattern may be formed simultaneously by a single patterning process, and no additional manufacturing process is needed to separately form the conductive pattern. As a result, it is possible to reduce the number of patterning processes of the display substrate and the manufacturing cost of the display substrate.

Of course, the conductive pattern may be formed of a same material and in a same layer as the touch electrode, but the touch electrode occupies a relatively large area, and this makes a relatively small layout space reserved for the conductive pattern. Therefore, it is alternative that the conductive pattern is formed of the same material and in the same layer as the touch electrode bridge.

Since the conductive pattern is connected in substantially parallel to the signal line, an electrical signal will be also transmitted on the conductive pattern. In order to prevent the electrical signal on the conductive pattern from interfering with the touch sensing of the touch electrode, a distance between the conductive pattern and the touch electrode is required to be relatively large. Optionally, the orthogonal projection of the conductive pattern on the base substrate of the display substrate does not coincide at all or in part with an orthogonal projection of the touch electrode on the base substrate.

Specifically, the signal line may be a Vss signal line. Of course, the signal line is not limited to the Vss signal line, and may be other types of signal lines. When the signal line is the Vss signal line, the conductive pattern can be connected in substantially parallel to the Vss signal line in a Pad region. In this way, it is possible to greatly reduce the resistance of the Vss signal line and to improve the situation in which there is excessive IR-drop and local heat since an excessively narrow Vss signal line has increased resistance when the AMOLED display product has a narrow bezel, and this is conducive to achieving the narrow border of the AMOLED display product. Typically, with the technical solution of the present disclosure, it is possible to reduce the border of the AMOLED display product to 0.5 mm or less.

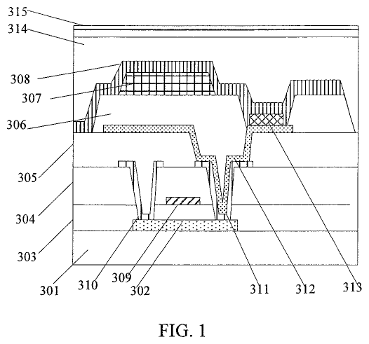

Specifically, FIG. 1 is a schematic cross-sectional view showing a display substrate according to an embodiment of the present disclosure. As shown in FIG. 1, the display substrate includes: a base substrate 301; an active layer 302 on the base substrate 301; a gate insulating layer 303; a gate electrode 309 on the gate insulating layer 303; an interlayer insulating layer 304; a source electrode 310 and a drain electrode 311 which are disposed on the interlayer insulating layer 304 and connected to the active layer 302 through via holes penetrating the interlayer insulating layer 304 and the gate insulating layer 303, respectively; a passivation layer 305; an anode 312 located on the passivation layer 305 and connected to the drain electrode 311 through a via hole penetrating the passivation layer 305; a defining layer 306 defining a light-emitting region; an organic light-emitting layer 313 located in the light-emitting region; a spacer layer 307; and a cathode 308, wherein under an electric field of the cathode 308 and the anode 312, the organic light-emitting layer 313 is capable of emitting monochromatic light of different colors. Among them, the active layer 302, the gate electrode 309, the gate insulating layer 303, the source electrode 310, and the drain electrode 311 constitute a driving thin film transistor, while the anode 312, the organic light-emitting layer 313, and the cathode 308 constitute a light-emitting unit. When the display substrate is in operation, a reference voltage signal is supplied to the cathode 308 through the Vss signal line. If the Vss signal line has a relatively small width, the Vss signal line will have relatively large resistance, and an electrical signal transmitted to the cathode 308 will be affected. Therefore, in this embodiment, a conductive pattern 315 is disposed on a thin film encapsulation layer 314 covering the display substrate, and the conductive pattern 315 is connected in substantially parallel to the Vss signal line in the Pad region. In this way, it is possible to greatly reduce the resistance of the Vss signal line and to improve the situation in which there is excessive IR-drop and local heat since an excessively narrow Vss signal line has increased resistance when the AMOLED display product has a narrow bezel, and this is conducive to achieving the narrow border of the AMOLED display product.

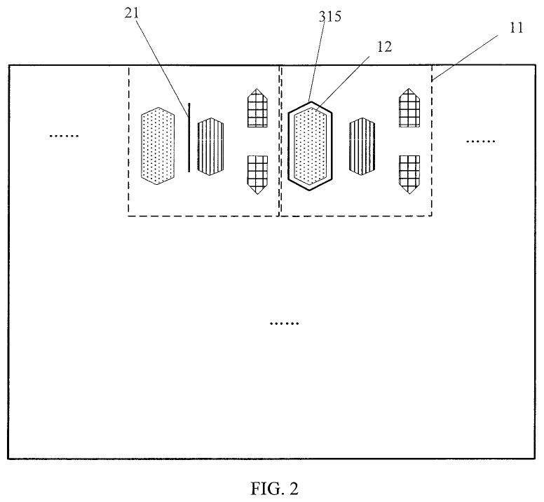

As shown in FIG. 2, the conductive pattern 315 may be disposed in the display region provided with a plurality of pixel units 11. Each of the pixel units 11 includes a plurality of sub-pixels 12. When the display substrate further incorporates a touch function, a touch electrode bridge 21 is disposed on the thin film encapsulation layer 314 of the display substrate. Therefore, the conductive pattern 315 may be made of a same material and in a same layer as the touch electrode bridge 21, so that the conductive pattern 315 and the touch electrode bridge 21 can be formed simultaneously by a single patterning process, and the conductive pattern 315 can be formed without increasing the number of patterning processes of the display substrate. As shown in FIG. 2, the layout of the conductive pattern 315 should not affect the layout of the touch electrode bridge 21, and should avoid the sub-pixel 12 so as to avoid affecting the display of the display substrate.

Another embodiment of the present disclosure provides a display device that includes the display substrate as described above. The display device may be any product or component having a display function, such as a television, a display, a digital photo frame, a mobile phone, a tablet computer, or the like. Moreover, the display device further includes a flexible circuit board, a printed circuit board, and a backplane.

A further embodiment of the present disclosure provides a method for manufacturing a display substrate that includes a display region, and a peripheral circuit which is located on a periphery of the display region and provided with a signal line. The method includes forming at least one conductive pattern connected in substantially parallel to the signal line on a thin film encapsulation layer of the display substrate.

In this embodiment, the conductive pattern is provided on the thin film encapsulation layer of the display substrate, and connected in substantially parallel to the signal line of the peripheral circuit of the display substrate. In this way, the resistance of the signal line of the peripheral circuit can be reduced, and it is not necessary to set the width of the peripheral circuit to be large so that enough space is reserved to increase the width of the signal line, thereby reducing the requirement for the wiring width of the peripheral circuit. As a result, it is possible to improve a situation in which there is excessive IR-drop and local heat since an excessively narrow Vss signal line has increased resistance when the AMOLED display product has a narrow bezel, and this is conducive to achieving the narrow border of the AMOLED display product.

Since an area of the display region is much larger than that of a region where the peripheral circuit is located, the display region has larger layout space, and the conductive pattern may be optionally arranged in the display region. In this way, it is possible to accommodate more conductive patterns, or to accommodate a conductive pattern to have a larger width. Therefore, it is possible to effectively reduce the resistance of the signal line of the peripheral circuit.

Specifically, the display substrate is an OLED display substrate, and includes a plurality of light-emitting units located in the display region. In order not to affect the display of the display substrate, the forming the conductive pattern specifically includes: forming, in the display region, the conductive pattern whose orthogonal projection on a base substrate of the display substrate does not coincide at all or in part with orthogonal projections of the light-emitting units on the base substrate.

Of course, when the conductive pattern is made of a transparent conductive material, the orthogonal projection of the conductive pattern on the base substrate of the display substrate may coincide with the orthogonal projections of the light-emitting units on the base substrate of the display substrate. However, the electrical conductivity of a metal material is generally better than that of a transparent conductive material. Therefore, the conductive pattern is alternatively made of a metal material such as Al, Cu, or Ag. Since the metal material is opaque, it is necessary to design the conductive pattern in such a manner that the orthogonal projection of the conductive pattern on the base substrate of the display substrate does not coincide at all or in part with the orthogonal projections of the light-emitting units on the base substrate.

Further, when the display substrate further incorporates a touch function, the display substrate further includes a touch electrode bridge and a touch electrode, which are located on the thin film encapsulation layer but disposed in different layers. In this case, the forming the conductive pattern specifically includes: forming the conductive pattern and the touch electrode bridge simultaneously by a single patterning process. In this way, it is not necessary to separately form the conductive pattern by an additional manufacturing process, which can reduce the number of patterning processes of the display substrate and the manufacturing cost of the display substrate.

Of course, the conductive pattern may be formed of a same material and in a same layer as the touch electrode, but the touch electrode occupies a relatively large area, and this makes a relatively small layout space reserved for the conductive pattern. Therefore, it is alternative that the conductive pattern is formed of the same material and in the same layer as the touch electrode bridge.

Since the conductive pattern is connected in substantially parallel to the signal line, an electrical signal will be also transmitted on the conductive pattern. In order to prevent the electrical signal on the conductive pattern from interfering with the touch sensing of the touch electrode, a distance between the conductive pattern and the touch electrode is required to be relatively large. Optionally, the orthogonal projection of the conductive pattern on the base substrate of the display substrate does not coincide at all or in part with an orthogonal projection of the touch electrode on the base substrate.

Specifically, the signal line may be a Vss signal line. Of course, the signal line is not limited to the Vss signal line, and may be other types of signal lines. When the signal line is the Vss signal line, the conductive pattern can be connected in substantially parallel to the Vss signal line in a Pad region. In this way, it is possible to greatly reduce the resistance of the Vss signal line and to improve the situation in which there is excessive IR-drop and local heat since an excessively narrow Vss signal line has increased resistance when the AMOLED display product has a narrow bezel, and this is conducive to achieving the narrow border of the AMOLED display product. Typically, with the technical solution of the present disclosure, it is possible to reduce the border of the AMOLED display product to 0.5mm or less.

In a specific embodiment, the method for manufacturing the display substrate includes the following steps.

In Step 1, a base substrate on which a driving thin film transistor and light-emitting units have been fabricated is encapsulated to form a thin film encapsulation layer, and a FMLOC (Flexible Multiple Layer On Cell) process is performed on the thin film encapsulation layer. For example, the FMLOC process is used to form a touch electrode bridge and a touch electrode on the thin film encapsulation layer. In the FMLOC process, two layers of metal patterns are required, of which a first layer of the metal patterns is a touch electrode bridge and a second layer of the metal patterns is a touch electrode.

In Step 2, when the first layer of the metal patterns is formed, in addition to the touch electrode bridge, a plurality of conductive patterns is formed in the display region and extends to a Pad region of the display substrate.

In Step 3, an insulating layer between the first layer of the metal patterns and the second layer of the metal patterns is formed. In the formation of the insulating layer, since the insulating layer covers the conductive pattern, it is necessary to form a via hole exposing the conductive pattern in the Pad region.

In Step 4, a second layer of the metal patterns is formed to include the touch electrode and a lead for leading the conductive pattern out.

In Step 5, after the fabrication of the touch electrode structure is completed, a FPC (Flexible Printed Circuit) is bonded to the Pad region of the display substrate. At the same time of bonding, the lead for the conductive pattern and the Vss signal line are connected in substantially parallel to each other at the line of the FPC.

In this embodiment, the conductive pattern is connected in substantially parallel to the Vss signal line in the Pad region, which can greatly reduce the resistance of the Vss signal line, and can improve a situation in which there is excessive IR-drop and local heat since an excessively narrow Vss signal line has increased resistance when the AMOLED display product has a narrow bezel, and this is conducive to achieving the narrow border of the AMOLED display product. Typically, with the technical solution of the present disclosure, it is possible to reduce the border of the AMOLED display product to 0.5 mm or less.

In the method embodiments of the present disclosure, the sequence numbers of the steps are not intended to limit the order of the steps. For those skilled in the art, variations in the order of the steps made without exercising creative work also fall within the protection scope of the present disclosure.

Unless otherwise defined, technical or scientific terms used herein should have the same meaning as commonly understood by those having ordinary skills in the art to which the present disclosure pertains. Terms such as “first” and “second” used herein are used merely to distinguish different constituent components rather than to indicate any sequence, number or importance. The terms “comprising”, “including” or other variants thereof are intended to means that the element or item stated before such terms encompasses elements, items and equivalents thereof listed after these terms without excluding other elements or items not expressly listed. The terms “connect”, “connected” or the like are not intended to define physical or mechanical connection, but may include an electrical connection, either direct or indirect. Such words as “up”, “down”, “left” and “right” are merely used to represent a relative positional relationship, and when an absolute position of the described object is changed, the relative position relationship will be changed accordingly.

It will be understood that when an element such as a layer, a film, an region or a substrate is referred to as being “on” or “under” another element, it can be directly “on” or “under” the other element, or an intervening element may be present.

The above are alternative embodiments of the present disclosure, and it shall be indicated that several improvements and modifications may be made by those having ordinary skills in the art with departing from the principle of the present disclosure, and such improvements and modifications shall also be regarded as falling within the protection scope of the present disclosure.

What is claimed is:

1. A display substrate, comprising:
a display region;
a peripheral circuit located on a periphery of the display region and provided with a signal line; and
at least one conductive pattern located on a thin film encapsulation layer of the display substrate and connected in substantially parallel to the signal line.

2. The display substrate according to claim 1, wherein the conductive pattern is located in the display region.

3. The display substrate according to claim 2, wherein the display substrate comprises a plurality of light-emitting units located in the display region, and an orthogonal projection of the conductive pattern on a base substrate of the display substrate does not coincide at all or in part with orthogonal projections of the light-emitting units on the base substrate.

4. The display substrate according to claim 1, wherein the display substrate further comprises a touch electrode bridge and a touch electrode, which are located on the thin film encapsulation layer but disposed in different layers, and the conductive pattern is formed of a same material and in a same layer as the touch electrode bridge.

5. The display substrate according to claim 4, wherein an orthogonal projection of the conductive pattern on a base substrate of the display substrate does not coincide at all or in part with an orthogonal projection of the touch electrode on the base substrate.

6. The display substrate according to claim 1, wherein the signal line is a Vss signal line; and
the display substrate is an Organic Light-Emitting Diode (OLED) display substrate or an Active-Matrix Organic Light-Emitting Diode (AMOLED) display substrate.

7. The display substrate according to claim 6, wherein when the display substrate is the AMOLED display substrate, its bezel has a width of 0.5 mm or less.

8. A display device, comprising a display substrate, wherein the display substrate comprises:
a display region;
a peripheral circuit located on a periphery of the display region and provided with a signal line; and
at least one conductive pattern located on a thin film encapsulation layer of the display substrate and connected in substantially parallel to the signal line.

9. The display device according to claim 8, wherein the conductive pattern is located in the display region.

10. The display device according to claim 9, wherein the display substrate comprises a plurality of light-emitting units located in the display region, and an orthogonal projection of the conductive pattern on a base substrate of the display substrate does not coincide at all or in part with orthogonal projections of the light-emitting units on the base substrate.

11. The display device according to claim 8, wherein the display substrate further comprises a touch electrode bridge and a touch electrode, which are located on the thin film encapsulation layer but disposed in different layers, and the conductive pattern is formed of a same material and in a same layer as the touch electrode bridge.

12. The display device according to claim 11, wherein an orthogonal projection of the conductive pattern on a base substrate of the display substrate does not coincide at all or in part with an orthogonal projection of the touch electrode on the base substrate.

13. The display device according to claim 8, wherein the signal line is a Vss signal line; and
the display substrate is an Organic Light-Emitting Diode (OLED) display substrate or an Active-Matrix Organic Light-Emitting Diode (AMOLED) display substrate.

14. The display device according to claim 13, wherein when the display substrate is the AMOLED display substrate, its bezel has a width of 0.5 mm or less.

15. A method for manufacturing a display substrate comprising a display region, and a peripheral circuit which is located on a periphery of the display region and provided with a signal line,
the method comprising:
forming at least one conductive pattern connected in substantially parallel to the signal line on a thin film encapsulation layer of the display substrate.

16. The method according to claim 15, wherein the display substrate comprises a plurality of light-emitting units located in the display region, and the forming the at least one conductive pattern comprises:
forming the at least one conductive pattern in the display region, wherein an orthogonal projection of the conductive pattern on a base substrate of the display substrate does not coincide at all or in part with orthogonal projections of the light-emitting units on the base substrate.

17. The method according to claim 15, wherein the display substrate further comprises a touch electrode bridge and a touch electrode, which are located on the thin film encapsulation layer but disposed in different layers, and the forming the at least one conductive pattern comprises:
forming the conductive pattern and the touch electrode bridge simultaneously by a single patterning process.

18. The method according to claim 15, wherein the forming the at least one conductive pattern connected in substantially parallel to the signal line on the thin film encapsulation layer of the display substrate is performed by a bonding process.

19. The method according to claim 15, further comprising forming a touch electrode bridge and a touch electrode on the thin film encapsulation layer of the display substrate by a Flexible Multiple Layer On Cell (FMLOC) process.

20. The method according to claim 15, wherein the manufactured display substrate is an Organic Light-Emitting Diode (OLED) display substrate or an Active-Matrix Organic Light-Emitting Diode (AMOLED) display substrate.
